(19) United States
(12) Patent Application Publication
(10) Pub. No.: US 2018/0242465 A1
(43) Pub. Date: Aug. 23, 2018

(54) FABRICATION OF METAL NANOWIRE MESHES OVER LARGE AREAS BY SHEAR-ALIGNMENT OF BLOCK COPOLYMERS

(71) Applicant: Lawrence Livermore National Security, LLC, Livermore, CA (US)

(72) Inventors: Anna Hiszpanski, Dublin, CA (US); Thomas Yong-Jin Han, Livermore, CA (US); Carla Lim Watson, Dublin, CA (US); Timothy Dexter Yee, Alameda, CA (US)

(21) Appl. No.: 15/441,146

(22) Filed: Feb. 23, 2017

(51) Int. Cl. H05K 3/46; H01B 1/22; H01B 1/24; H05K 1/02; H01B 13/00; H05K 3/02

(52) U.S. Cl. CPC H05K 3/4644; H01B 1/22; H01B 1/24; H05K 2201/026; H01B 13/0036; H05K 3/027; H05K 1/0274

(57) ABSTRACT

According to one embodiment, a method for creating a metal nanowire mesh the method includes forming a first layer of block copolymer, causing the block copolymer to become aligned in approximately straight lines, infiltrating one phase of the block copolymer with a metal, and removing the block copolymer where the metal remains after the block copolymer is removed. Furthermore, the method includes forming a second layer of block copolymer, causing the block copolymer in the second layer to become ordered in approximately straight lines oriented at an angle from greater than 0 degrees to 90 degrees from a mean direction of longitudinal axes of the remaining metal, infiltrating one phase of the block copolymer in the second layer with a second metal, and removing the block copolymer in the second layer where the second metal remains above the metal after the block copolymer in the second layer is removed.

The United States Government has rights in this invention pursuant to Contract No. DE-AC52-07NA27344 between the United States Department of Energy and Lawrence Livermore National Security, LLC for the operation of Lawrence Livermore National Laboratory.

### FIELD OF THE INVENTION

The present invention relates to transparent conductive coating material, and more particularly, this invention relates to metal nanowire meshes.

### BACKGROUND

Conductive and transparent coatings are used for a variety of electronic applications, such as solar cells and electronic displays. Indium tin oxide (ITO) is the current standard coating material but has many drawbacks. ITO is costly due to the limited amounts of indium available. In addition, because of lack of flexibility of ITO layers and costly layer deposition process, ITO is incompatible with many plastic substrates that may be used in next-generation flexible electronics. Thus, it is desirable to develop conductive coatings using easily sourced or manufactured materials that have high conductivity and high transmissivity. Furthermore, it is desirable to be able to deform the coating without loss of performance, i.e. while still maintaining conductivity and transmissivity.

A number of materials currently being researched may address these needs. To date, metal nanowire networks and metal wire meshes appear to perform better than conductive polymers and graphene. Metal nanowire networks are formed by depositing nanowires onto a surface without any or little ordering or control over the assembly of the nanowires. Such disordered metal nanowire networks have shown excellent transmissivity, especially at low concentrations of nanowires. However, the disordered nature of the nanowires results in lower conductivity. Conversely, patterned metal wire meshes are ordered, which maximizes the number electrical junctions between wires and yields high conductivity. However, the patterning strategies to form the ordered meshes over large and device-relevant areas necessitate that the wires be microns in diameter, which results in reduced transmissivity.

Accordingly, to attain both high conductivity and high transmissivity, it would be desirable to produce metal wire meshes with nanometer dimensions and defined geometries. In addition, a scalable method is needed to form metal nanowire meshes over wafer-scale areas. Currently, techniques to fabricate metal nanowire meshes either provide excellent control over ordering but are not scalable to large areas (i.e., nanofabrication techniques like electron beam lithography limited to μm²-areas) or are scalable to large areas but do not provide control over the precise placement of nanowires, thereby creating a disordered network of nanowires rather than a mesh (i.e., deposition of nanowires).

### SUMMARY

According to one embodiment, a method for creating a metal nanowire mesh the method includes forming a first layer of block copolymer, causing the block copolymer to become aligned in approximately straight lines, infiltrating one phase of the block copolymer with a metal, and removing the block copolymer where the metal remains after the block copolymer is removed. Furthermore, the method includes forming a second layer of block copolymer, causing the block copolymer in the second layer to become ordered in approximately straight lines oriented at an angle from greater than 0 degrees to 90 degrees from a mean direction of longitudinal axes of the remaining metal, infiltrating one phase of the block copolymer in the second layer with a second metal, and removing the block copolymer in the second layer where the second metal remains above the metal after the block copolymer in the second layer is removed.

According to another embodiment, a method for creating a metal nanowire mesh includes forming a first layer of block copolymer, causing the block copolymer to become ordered in approximately straight lines, and inducing crosslinking in the block copolymer. Moreover, the method includes forming a second layer of block copolymer above the first layer, causing the block copolymer in the second layer to become ordered in approximately straight lines oriented at an angle from greater than 0 degrees to 90 degrees from a mean direction of longitudinal axes of the lines of the first layer, infiltrating one phase of the block copolymer in each layer with a metal, and removing the block copolymers in the first and second layers whereby the metal remains after the block copolymer is removed.

According to yet another embodiment, a metal nanowire mesh includes first metal wires oriented in approximately straight lines and second metal wires on the first metal wires. The second metal wires are oriented in approximately straight lines oriented at an angle from greater than 0 degrees to 90 degrees from a mean direction of the lines of the first metal wires. In addition, an average diameter of at least one of the first and second metal wires is in a range of about 8 to about 50 nanometers.

Other aspects and advantages of the present invention will become apparent from the following detailed description, which, when taken in conjunction with the drawings, illustrate by way of example the principles of the invention.

### BRIEF DESCRIPTION OF THE DRAWINGS

FIG. 1 is a flowchart of a method according to one embodiment.

FIG. 2 is a diagram drawing of a method according to one embodiment.

FIG. 3A is an atomic force microscope image of the topography of a sample after spin-coating a PS-P2VP film according to one embodiment.

FIG. 3B is an atomic force microscope image of the topography of a sample after shear-alignment and soaking the PS-P2VP film in a Na₂PtCl₄ solution according to one embodiment.

FIG. 3C is an atomic force microscope image of the topography of a sample after O₂ plasma etching according to one embodiment.

FIG. 3D is an atomic force microscope image of the topography of a sample after sintering under a reducing atmosphere according to one embodiment.

FIG. 4A is an atomic force microscope image of the topography of a platinum nanowire mesh according to one embodiment.

FIGS. 4B and 4C are scanning electron microscope images of a platinum nanowire mesh at two magnifications according to one embodiment.

FIG. 5 is a flowchart of a method according to one embodiment.

FIG. 6 is a diagram drawing of a method according to one embodiment.

FIG. 7 is a flowchart of a method according to one embodiment.

FIG. 8 is a diagram drawing of a method according to one embodiment.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

The following description discloses several preferred embodiments of metal nanowire mesh and/or related systems and methods.

In one general embodiment, a method for creating a metal nanowire mesh the method includes forming a first layer of block copolymer, causing the block copolymer to become aligned in approximately straight lines, infiltrating one phase of the block copolymer with a metal, and removing the block copolymer where the metal remains after the block copolymer is removed. Furthermore, the method includes forming a second layer of block copolymer, causing the block copolymer in the second layer to become ordered in approximately straight lines oriented at an angle from greater than 0 degrees to 90 degrees from a mean direction of longitudinal axes of the remaining metal, infiltrating one phase of the block copolymer in the second layer with a second metal, and removing the block copolymer in the second layer where the second metal remains above the metal after the block copolymer in the second layer is removed.

In another general embodiment, a method for creating a metal nanowire mesh includes forming a first layer of block copolymer, causing the block copolymer to become ordered in approximately straight lines, and inducing crosslinking in the block copolymer. Moreover, the method includes forming a second layer of block copolymer above the first layer, causing the block copolymer in the second layer to become ordered in approximately straight lines oriented at an angle from greater than 0 degrees to 90 degrees from a mean direction of longitudinal axes of the lines of the first layer, infiltrating one phase of the block copolymer in each layer with a metal, and removing the block copolymers in the first and second layers whereby the metal remains after the block copolymer is removed.

In yet another general embodiment, a metal nanowire mesh includes first metal wires oriented in approximately straight lines and second metal wires on the first metal wires. The second metal wires are oriented in approximately straight lines oriented at an angle from greater than 0 degrees to 90 degrees from a mean direction of the lines of the first metal wires. In addition, an average diameter of at least one of the first and second metal wires is in a range of about 8 to about 50 nanometers.

There is a need to develop conductive coatings that are easily sourced or manufactured that have high conductivity, high transmissivity, and can be deformed without loss in performance.

Through the development of scalable fabrication techniques for negative index metamaterial (NIMs), the inventors discovered a novel approach to the fabrication of metal nanowire meshes. Specifically, NIMs typically have a mesh-type lattice structure consisting of alternating layers of metal and dielectric materials, and the inventors used the directed assembly of block copolymers in order to form such structures.

Various embodiments described herein were developed in the course of fabricating metal mesh layers to build the more complex composite lattice structure necessary for NIMs. These embodiments may be useful for fabricating transparent electrodes.

The presently disclosed inventive concepts include a technique for making a large area of mesh in the range of cm² with metal nanowires that are less than 50 nanometers (nm) in diameter using methods of shear alignment of block copolymers followed by metal infiltration. The geometry of the transparent metal nanowire mesh described herein may achieve high conductivity and, simultaneously, the small dimensions of the nanowires may allow the nanowire mesh to achieve high transmissivity. These block copolymer-derived metal meshes can also be used as a mask to transfer the mesh pattern into the underlying substrate, thereby creating a large-area stamp of a nanowire-scale mesh. Other material (e.g., metals, polymers, molecules) can be deposited atop the stamp and then stamped or transferred to other receiving substrates to create nanowire meshes of a much greater variety of materials.

Methods to Fabricate Metal Nanowire Mesh

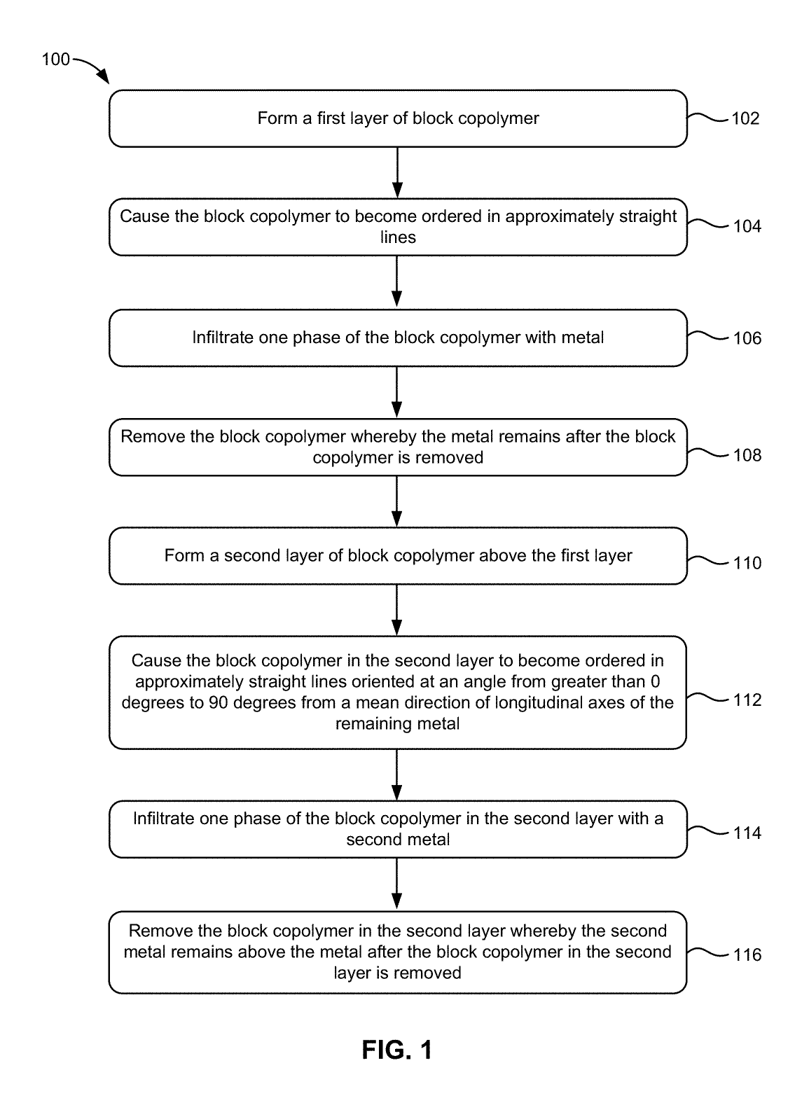

FIG. 1 shows a method 100 for creating metal nanowire mesh, in accordance with one embodiment. As an option, the present method 100 may be implemented to create structures and devices such as those shown in the other FIGS. described herein. Of course, however, this method 100 and others presented herein may be used to form structures for a wide variety of devices and/or purposes which may or may not be related to the illustrative embodiments listed herein. Further, the methods presented herein may be carried out in any desired environment. Moreover, more or less operations than those shown in FIG. 1 may be included in method 100, according to various embodiments. It should also be noted that any of the aforementioned features may be used in any of the embodiments described in accordance with the various methods.

According to one embodiment, the method 100 for creating a metal nanowire mesh starts with a block polymer (BCP). BCPs are composed of two or more covalently-linked and chemically-distinct polymeric units or blocks. Depending on the chemical compatibility of the blocks and degree of polymerization, the BCPs will microphase separate in the bulk to minimize unfavorable interfaces, thereby forming one of several potential regular nanoscale structures with 10-100 nm periodicities, including hexagonally packed cylinders and spheres. In a preferable embodiment of method 100, BCPs may be used that have one phase that complexes with metal salts and the BCP naturally phase separates and assembles into patterns having 100 nm spacing. Furthermore, the BCPs preferably have either a spherical, cylindrical, or lamellar phase, all of which are amenable to uniaxial alignment via shear stresses.

Known block copolymers generally having one or more of the foregoing properties may be used in the various processes provided herein, as would become apparent to one skilled in the art upon reading the present description. Illustrative block copolymers that may be used in various embodiments include, but are not limited to, poly(styrene)-poly(2-vinyl pyridine), poly(styrene)-poly(4-vinyl pyridine), poly(styrene)-poly(methyl methacrylate), poly(styrene)-poly(acrylic acid), and poly(styrene)-poly(ferrocenyl dimethyl silane).

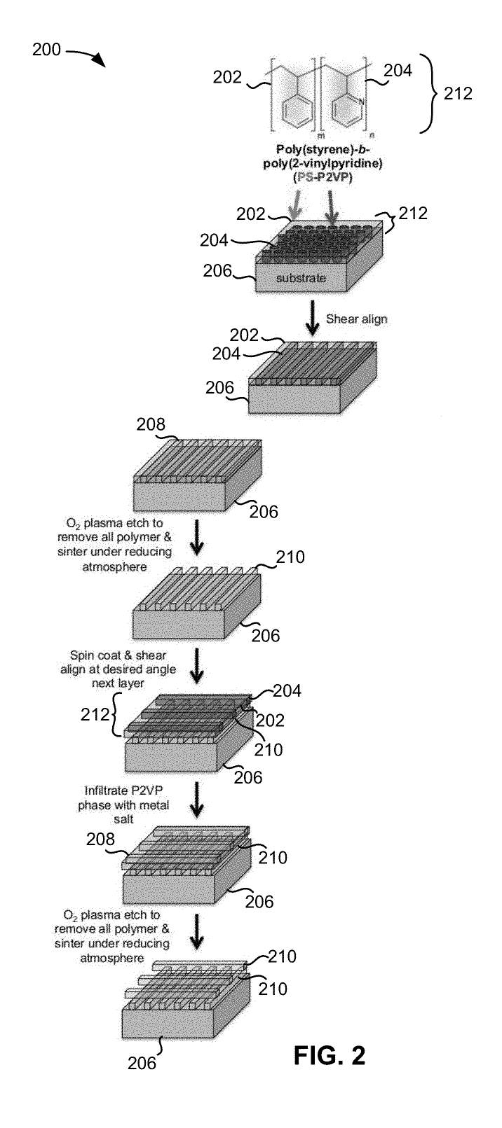

In an exemplary embodiment, method 100 begins with the BCP 212 poly(styrene)-poly(2-vinylpyridine) (PS-P2VP) as illustrated in one embodiment of the method 200 of forming a metal nanowire mesh at the top of FIG. 2. The two phases of this BCP 212, are the PS 202 and the P2VP 204. In one approach, one of the phases of the BCP 212, in this case the P2VP 204 phase, complexes with metal salts thereby enabling direct metal patterning prescribed by the ordering of the BCP 212. In other approaches, BCPs 212 such as poly(styrene)-poly(4-vinylpyridine) may be used.

Looking to FIG. 1, the first step 102 of method 100 includes forming a first layer of BCP. As shown in FIG. 2, in some embodiments, step 102 may involve spin coating onto a substrate 206 a first layer of BCP 212 from solution to form a thin film (for example, with a thickness of ca. 40 nm) of the combination of two phases PS 202, P2VP 204 of BCP 212. In some approaches, the substrate 206 may be silicon. Other techniques for film formation may include but not limited to doctor/knife blading, printing, dropcasting, etc.

As deposited (and illustrated in FIG. 2), the BCP 212 may phase separate to form hexagonally closed packed cylinders, as shown with the P2VP 204, in the second phase PS 202.

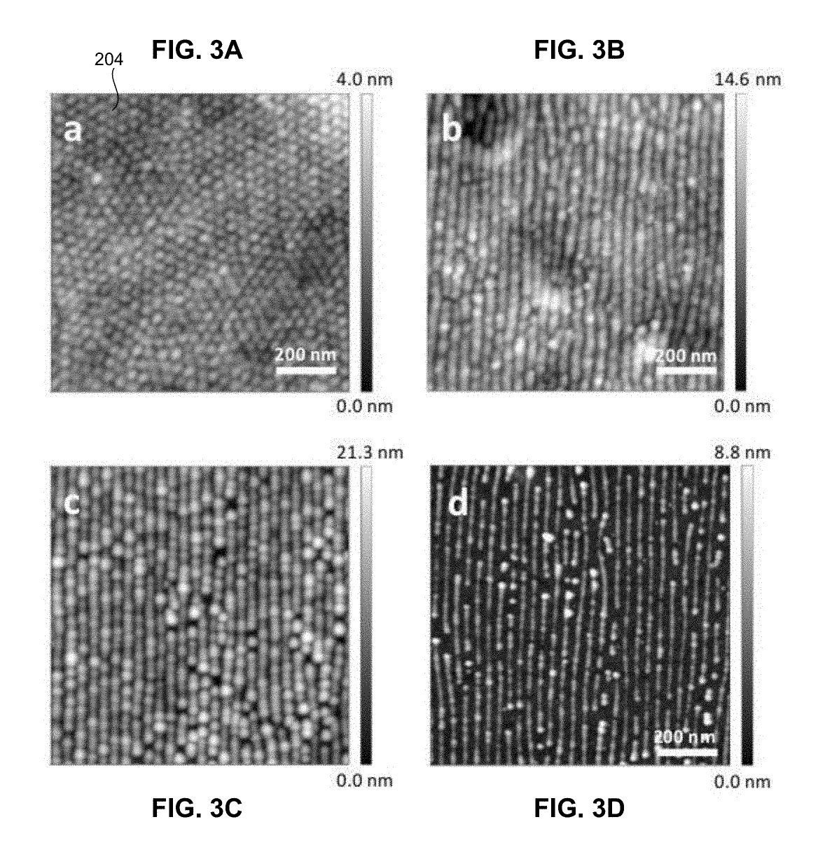

To further illustrate the sample of BCP spin-coated onto a substrate, FIG. 3A is an atomic force microscope (AFM) image of the topography of a sample of BCP (PS-P2VP) film after spin-coating onto a substrate. The hexagonally close-packed standing cylinders or spheres of the P2VP 204 phase are visible in the image. The different shadings of the hexagonal cylinders or spheres reflect the variation in topography depicted in the AFM image.

According to one embodiment, the step 104 of method 100, as shown in FIG. 1, involves causing the BCP to become ordered in approximately straight lines. In one embodiment, the approximately straight lines of the aligned BCP indicate that the component parts of the BCP may be generally aligned with the direction of applied shear force. Furthermore, less than 10% of the lines by length of the aligned BCP may be more than 15 degrees from a straight line oriented in the direction of shear force.

In an exemplary embodiment, as shown in FIG. 2, alignment by shear force may cause the P2VP 204 phase to form straight lines (dark lines) and the second phase PS 202 (lighter lines) form straight lines between the P2VP 204 lines.

Various embodiments of step 104 of method 100 may use conventional methods of aligning BCPs to induce long-range ordering, for example, heating and mechanically applied shear force, thermal gradients, solvent swelling gradients, etc. All these methods of shear aligning BCPs into parallel lines typically involve placing a silicone rubber stamp, for example poly(dimethylsiloxane) (PDMS), in contact with a heated BCP film. For methods of shear-alignment using thermal gradients (which can be laser-induced or part of a hotplate design) or solvent swelling, heat or solvent vapors depending on the treatment cause expansion of PDMS, which in turn induces local shear stresses at the PDMS-BCP interface and alignment of the BCP parallel to the shear stress.

In an exemplary method of using mechanically induced shear force alignment of the BCP film, a weight may be placed on top of the PDMS in contact with the BCP film and the weight may then be laterally pulled. The shear stress between the PDMS and the BCP film may cause the BCP to reorder into parallel lines with long-range ordering in the direction of the applied force.

In other embodiments, step 104 of method 100 may include conventional methods of aligning BCPs following phase separation.

Looking to FIG. 1, causing the BCP to become ordered in approximately straight lines, step 106 of method 100 involves infiltrating (for example, adding, complexing, soaking, etc.) one phase of the BCP with a metal. As illustrated in FIG. 2, a shear aligned sample with the parallel lines of phase 204 BCP may be soaked in an acidic metal salt solution 208 to infiltrate the P2VP 204 phase with metal. In some embodiments, the metal anion (or possibly cation) infiltrates the shear aligned BCP and may complex with the aligned phase of the BCP. In some approaches, sodium tetrachloroplatinate (II) Na₂PtCl₄ may be used to fabricate platinum nanowire meshes. In other approaches, chloroauric acid (HAuCl₄) may be used to fabricate gold nanowire meshes. In yet other approaches, other metal salts may be used to fabricate nanowires of other metals including, but not limited to, Ag, Pd, Fe, Co, Cu, and Ni.

Looking to FIG. 3B, an AFM image of an exemplary embodiment shows the shear aligned BCP film after soaking in an acidic Na₂PtCl₄ solution. The platinum anion has infiltrated the P2VP phase thereby causing a greater variance in the height between the PS (dark lines) and P2VP phases (light and varying bright lines).

Referring back to FIG. 1, step 108 of method 100 includes removing the BCP whereby the metal may remain generally in the shape of the aforementioned straight line of the phase in which it was infiltrated after the BCP has been removed. In some embodiments of step 108, as illustrated in FIG. 2, the sample with metal salt 208 infiltrated in the one phase 204 of BCP may be subjected to oxygen plasma, which etches away the organic material, such as polymer, leaving behind only the patterned metal 210. Oxygen etching may be done following conventional methods known in the art.

Looking to FIG. 3C, an AFM image of an exemplary embodiment shows the metal (Pt) pattern following oxygen etching. In this image the BCP has been removed leaving only generally parallel lines of the metal (Pt).

In a preferred embodiment as illustrated in FIG. 2, after removing the BCP etching with oxygen plasma, the method may include sintering the metal prior to forming the second layer of block copolymer. Sintering the metal, by putting the substrate with metal infiltration in a furnace at high temperature under a reducing atmosphere, reduces the metal salt to a metal and may increase conductivity of the metal 210 nanowires. The metal 210 nanowires may undergo some shrinkage during sintering. Sintering may be done following conventional methods known in the art.

Looking to FIG. 3D, an AFM image of an exemplary embodiment shows the nanowires as depicted by the generally parallel lines after sintering. From the image, sintering appears to cause the nanowires to shrink.

Referring back to FIG. 1, step 110 of method 100 involves forming a second layer of block copolymer which may be the same or different than the block copolymer used in the first layer. As shown in FIG. 2, an exemplary embodiment of method 100 of forming a mesh of nanowires, step 110 includes forming a second layer of BCP 212 by spin coating the same BCP 212 as used in the first layer onto the first layer of sintered metal 210 nanowires. In some approaches, the BCP used in the second layer may be different than the BCP used in the first layer.

Step 112 of method 100 involves causing the BCP of the second layer to become ordered in approximately straight lines oriented at an angle from greater than 0 degrees to 90 degrees from a mean direction of longitudinal axes of the remaining metal. In one embodiment, the second layer of BCP may be shear aligned into approximately straight lines that may be aligned with the direction of applied shear force. Moreover, less than 10% of the lines by length of the second layer of BCP may be more than 15 degrees from a straight line oriented in the direction of shear force. In some approaches, the geometry of the mesh may be determined by the direction of shear alignment of the second layer with respect to the first. In other approaches, the choice of BCP parameters that may dictate the nanowire dimensions.

As illustrated in FIG. 2, steps 110 and 112 of an exemplary embodiment of method 100 show the parallel lines of phase 204 of BCP 212 in the second layer are positioned 90 degrees from the first layer (perpendicular) following mechanically induced shear force alignment. In other approaches, step 112 of method 100 may use conventional methods of aligning BCPs to induce long-range ordering, for example, heating and shear force, thermal gradients, solvent swelling, etc.

Referring to FIG. 1, step 114 of method 100 involves infiltrating (adding, complexing, soaking, etc.) one phase of the block copolymer in the second layer with a second metal which may be the same or different as the metal formed in the first layer. In an exemplary embodiment of method 100 as shown in FIG. 2, the second metal 208 used to infiltrate the second layer may have the same composition as the first metal 208 used to infiltrate the first layer of BCP 212. In some approaches, the first metal and the second metal have different compositions.

In one embodiment of method 100, at least one of the infiltrating steps, step 106 and step 114, includes soaking the respective layer in a metal salt solution.

Referring back to FIG. 1, step 116 of method 100 involves removing the BCP in the second layer whereby the second metal remains generally in the shape of the aforementioned straight line of the phase in which it was infiltrated above the metal after the BCP in the second layer is removed. In some embodiments as illustrated in FIG. 2, the method used to remove the BCP 212 from the second layer may be etching with oxygen plasma. A preferred embodiment of method 100 includes sintering the second metal 208 under reduced atmosphere after removing the block copolymer 212 in the second layer thereby resulting in metal nanowire mesh 210

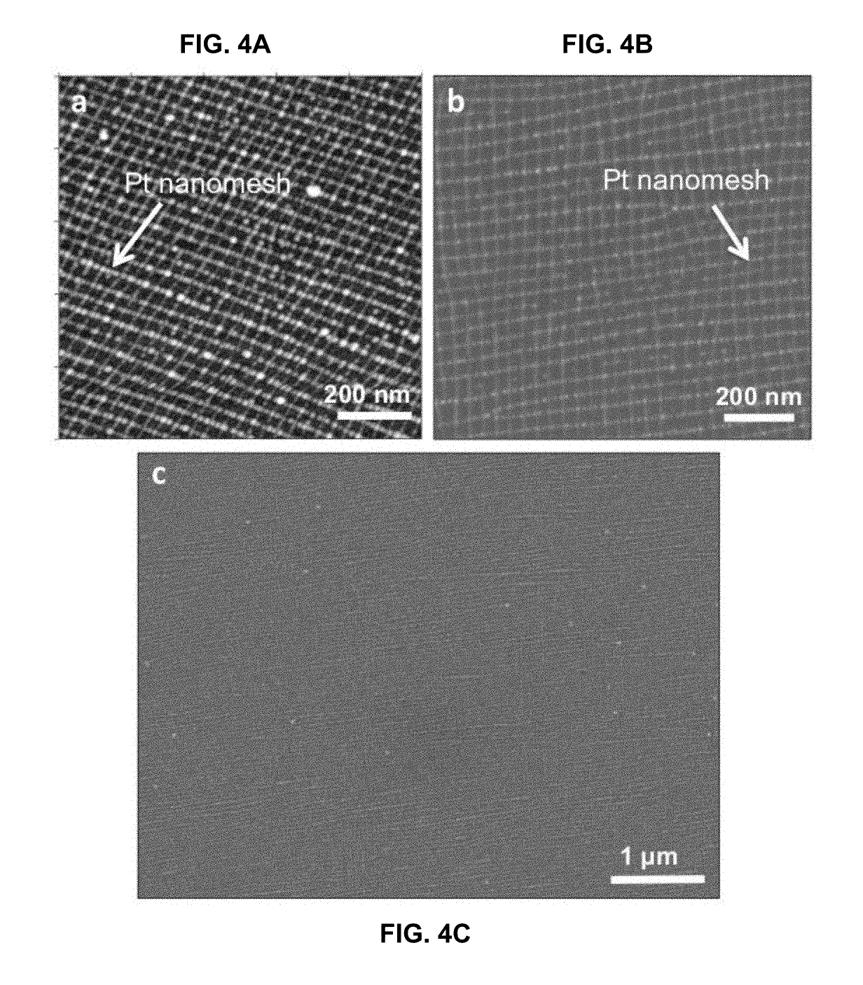

FIG. 4A shows an AFM image of a two-layer, square geometry platinum nanowire mesh fabricated following the method 100 as described above. FIG. 4B shows a scanning electron microscope (SEM) image at 200 nm of the platinum nanowire mesh relative to the same sample in FIG. 4A. FIG. 4C shows a SEM image of the platinum nanowire mesh at 1 μm (5 times wider scope). The images show the evenness of the mesh geometry at close microscopy (200 nm) and wide image (1 μm). The samples in these images were fabricated using the same BCP for both layers and the direction of shear alignment for the top layer was 90 degrees relative to the bottom layer and, thus, a square pattern was produced. In other approaches, varying the BCP ratio of blocks and molecular weights and/or changing the direction of the shear alignment of each layer may produce other geometries of metal nanowire mesh.

The method described above involves each layer of BCP undergoing metal infiltration followed by oxygen etching to remove the BCP. An alternative embodiment of a method to fabricate metal nanowire mesh involves forming multiple layers of aligned BCP in which each layer may be oriented at an angle of approximately 90 degrees from the layer underneath, and then the method includes a single metal infiltration and oxygen etching step to form the metal nanowire mesh. The method described as follows allows patterning of the metal nanowire mesh on a substrate.

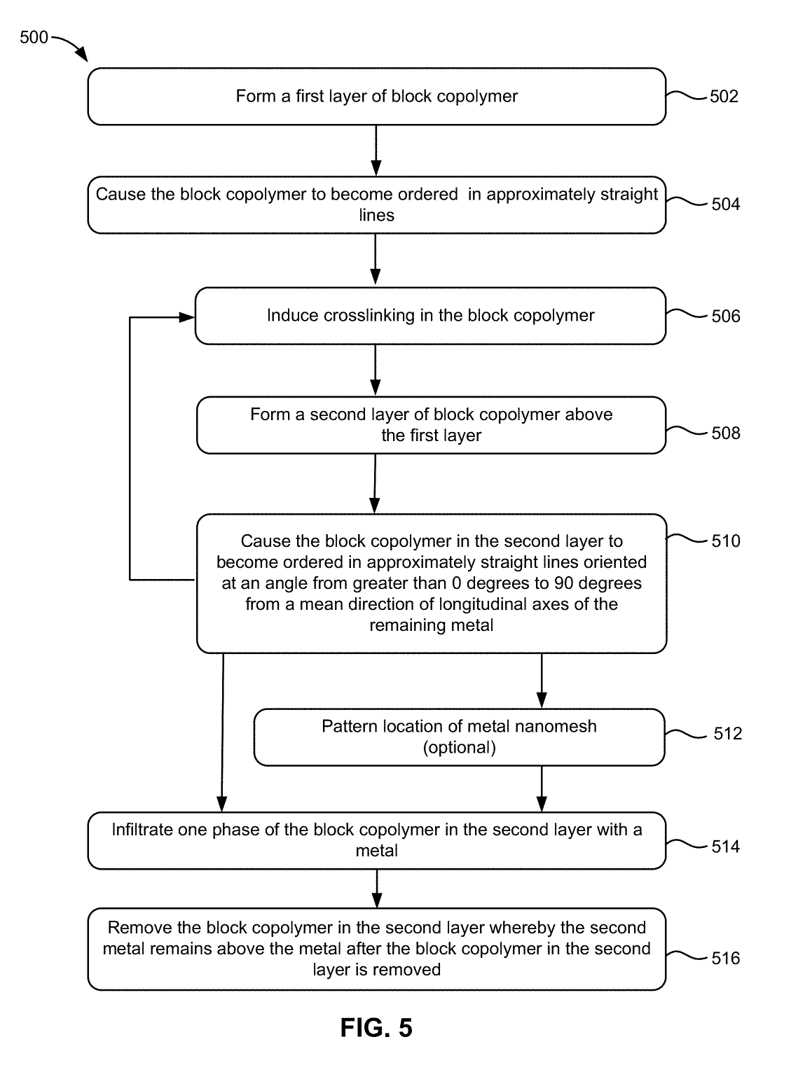

FIG. 5 shows a method 500, according to one embodiment, for creating metal nanowire mesh, in accordance with one embodiment. As an option, the present method 500 may be implemented to create structures, devices such as those shown in the other FIGS. described herein. Of course, however, this method 500 and others presented herein may be used to form structures for a wide variety of devices and/or purposes which may or may not be related to the illustrative embodiments listed herein. Further, the methods presented herein may be carried out in any desired environment. Moreover, more or less operations than those shown in FIGS. 1, 2, 5 and 6 may be included in method 500, according to various embodiments. It should also be noted that any of the aforementioned features may be used in any of the embodiments described in accordance with the various methods.

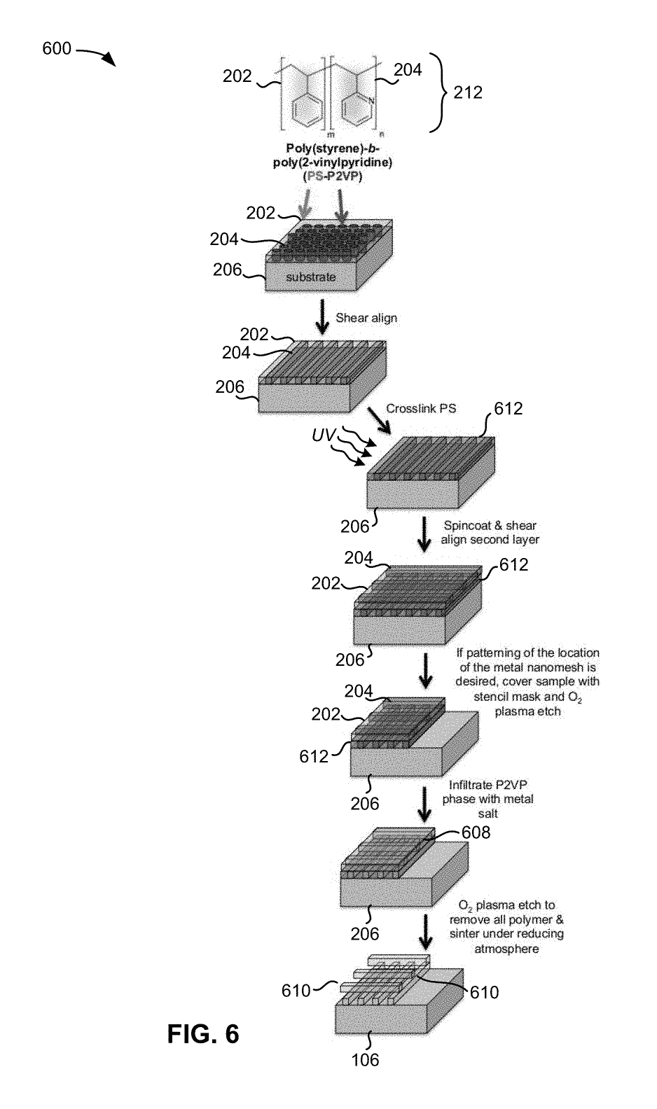

Looking to FIG. 5 the first step 502 of method 500 includes forming a first layer of BCP as described in detail for step 102 of method 100 above. As illustrated in FIG. 6, step 502 shows a substrate 206 onto which the BCP 212 is spin coat from solution to form a thin film (for example, ca. 40 nm) of the combination of two phases PS 202, P2VP 204 of BCP 212. In some approaches, the substrate 206 may be silicon. Other techniques for film formation may include but are not limited to doctor/knife blading, printing, dropcasting, etc. As deposited (and illustrated in FIG. 6 of one embodiment of the method 600), the BCP 212 phase separates to form hexagonally closed packed cylinders or spheres, as shown with the P2VP 204, in the second phase PS 202.

Step 504 of method 500, as shown in FIG. 5, involves causing the BCP to become ordered in approximately straight lines, where approximately straight lines means that the component parts may be generally aligned with the direction of applied shear force. Furthermore, less than 10% of the lines by length may be more than 15 degrees from a straight line oriented in the direction of shear force. In an exemplary embodiment, as shown in FIG. 6, following mechanically induced shear force alignment, the P2VP 204 phase form straight lines (dark) and the second phase PS 202 form straight lines between the P2VP 204 lines. As described above for step 102 of method 100, step 504 of method 500 may involve conventional methods of shear aligning BCPs to induce long-range ordering.

Step 506 of method 500 involves fixing the shear aligned underlayer of BCP so that a second layer of BCP may be spin coated and aligned on top without the underlayer dissolving due to the solvent of the spin coating step. Following shear alignment of BCP on the substrate in step 504, step 506 involves inducing crosslinking in the BCP. In an exemplary embodiment as shown in FIG. 6, the film of shear aligned BCP 212 on the substrate may be exposed to high intensity ultraviolet (UV) light to induce crosslinking of the polystyrene (PS) 202 block of the BCP 212 using methods known in the art. Without wishing to be bound by any theory, the inventors believe crosslinking the PS 202 reduces the solubility of the BCP 212, in this case PS-P2VP 212, film thereby allowing deposition and shear-alignment of a second BCP atop the first without disturbing the underlying layer. As illustrated in FIG. 6, following shear alignment, the BCP 212 film may be crosslinked by UV irradiation thereby fixing the PS 202 in the now insoluble and crosslinked BCP 612.

Referring back to FIG. 5, step 508 of method 500 involves forming a second layer of block copolymer which may be the same or different than the block copolymer used in the first layer. In an exemplary embodiment to form a mesh of nanowires as illustrated in FIG. 6, the BCP 212 used in the second layer may be the same as the BCP 212 used in the first layer. In some approaches, the BCP used in the second layer may be different than the BCP used in the first layer.

Step 510 of method 500 involves causing the BCP to become ordered in approximately straight lines oriented at an angle from greater than 0 degrees to 90 degrees from a mean direction of longitudinal axes of the lines of the first layer. Moreover, the BCP forming approximately straight lines may mean that the component parts are generally aligned with the direction of applied shear force. Furthermore, less than 10% of the lines by length may be more than 15 degrees from a straight line oriented in the direction of shear force. In some approaches, the geometry of the mesh may be determined by the direction of shear alignment of the second layer with respect to the first. In other approaches, the choice of BCP parameters may dictate the nanowire dimensions.

In some embodiments, after aligning the second layer of BCP in approximately straight lines, method 500 may involve adding three, four, or more layers of BCP as indicated in FIG. 5 by the arrow from step 510 back to step 506 and repeating steps 506, 508, and 510.

When the desired number of layers of BCP is formed, as an option, the metal nanowire mesh may be patterned on the substrate. In one embodiment of method 500, and looking to FIG. 5, an optional step 512 may be included and involves patterning specific locations of the BCP on the substrate. In one embodiment of method 500, optional step 512 may involve masking the layers of BCPs and removing an unmasked portion thereof for patterning the layers prior to the infiltrating. In some approaches, locations may be patterned by applying a stencil mask to the two-layer shear aligned BCP in which the first layer is crosslinked. Then oxygen etching using conventional oxygen plasma techniques may remove those areas exposed by the stencil masks. As illustrated in FIG. 6, a stencil mask may be removed after oxygen etching of optional step 512 allowing the remaining two-layer BCP mesh to be infiltrated with metal 608.

Referring to FIG. 5, step 514 of method 500 involves infiltrating (adding, complexing, soaking, etc.) one phase of the block copolymer in each layer with a metal. In an exemplary embodiment as illustrated in FIG. 6, infiltrating the multi-layer aligned and crosslinked BCP 612 film may involve soaking in an acidic metal solution where the metal anion (or possible cation) infiltrates 608 and may complex with the P2VP 204 phase of the BCP 212.

Looking back to FIG. 5, step 516 of method 500 involves removing the BCPs in the first and second layers where the metal may remain generally in the shape of the aforementioned straight lines of the phases in which it was infiltrated after the BCP is removed. As before in step 108 of method 100 (see FIGS. 1-2), and illustrated in FIG. 6, the crosslinked BCP 612 sample with metal salt 608 infiltrated on the one phase 204 of BCP may be subjected to oxygen plasma which etches away organic material, including the polymer BCP, thereby leaving behind the patterned metal 610. Oxygen etching may be done following conventional methods known in the art.

In a preferred embodiment, the method 500 at step 516 includes sintering the metal under a reducing atmosphere after removing the BCPs. Sintering the metal may increase conductivity of the metal 610 nanowires (step 516 in FIG. 5). As shown in FIG. 6, the metal 610 nanowires may undergo some shrinkage during sintering. Sintering may be done following conventional methods known in the art.

Tuning the Fabrication of Metal Nanowire Mesh

Various embodiment described herein may be modified to tune the fabrication of metal nanowire mesh according to specific applications. By using different copolymers and/or metallic solution parameters, different dimensions of the metal nanowire mesh may be fabricated.

Some embodiments of methods described herein involve an infiltrating step (steps 106 and 114, FIG. 1 or step 514, FIG. 5) that may include soaking the layers of BCP in a metal salt solution. As above, if differing metal compositions are desired, the first layer may be infiltrated with a first metal, and the second metal applied to both layers thereafter. The first metal may be expected to remain for the most part in the first layer.

In some embodiments of method 100 and method 500, the average diameter of the metal (e.g. metal wires) from the first layer and/or the second metal following removal of the first and/or second layers of BCP from the metal infiltrated BCP (steps 108 and 116, FIG. 1, step 516, FIG. 5) may be in a range of about 8 to about 50 nanometers. Although sintering tends to reduce the average diameter of the metal nanowires from its pre-sintering size, this range applies to both sintered and unsintered metal lines.

In some embodiments of methods described herein, the metal lines can be formed to have an approximately equal average diameter. In other embodiments, the diameters can be tuned to be different. For example, in one approach, one embodiment may have an average diameter of the metal from the first layer may be at least 10% greater than an average diameter of the second metal. In another approach, one embodiment may have an average diameter of the metal from the first layer may be at least 10% smaller than an average diameter of the second metal.

Furthermore, in various embodiments of method described herein, an average spacing between commonly-aligned strips (e.g., generally parallel) of at least one of the metals in the formed nanowire mesh may be in a range of about 30 to about 100 nanometers.

Metal Nanowire Mesh

Various embodiments of methods described herein fabricate a metal nanowire mesh that includes first metal wires oriented in approximately straight lines, second metal wires on the first metal wires, the second metal wires being oriented in approximately straight lines oriented at an angle from greater than 0 degrees to 90 degrees from a mean direction of the lines of the first metal wires where an average diameter of at least one of the first and second metal wires may be in a range of about 8 to about 50 nanometers.

FIG. 4A is an AFM image of a two layer, square geometry platinum nanowire mesh on silicon that shows the three dimensionality of the nanowire mesh formed by the methods described herein. FIGS. 4B and 4C are SEM images of the same sample of platinum nanowire mesh at two different magnifications. FIG. 4C shows the uniform fabrication metal nanowire mesh over a large area.

One embodiment of the metal nanowire mesh includes an average spacing between the first metal wires may be in a range of about 30 to about 100 nanometers.

Another embodiment of the metal nanowire mesh includes an average spacing between the first metal wires that may vary by less than 20% along lengths thereof, and preferably by less than 15% and ideally by less than 10% along lengths thereof. This minimal variation may be present in spite of instances of a “Y” where two wires merge into one.

Yet another embodiment of the metal nanowire mesh includes where the first metal wires may differ from the second metal wires in composition. In one approach of the metal nanowire mesh, the first metal wires may differ from the second metal wires in average diameter. In another approach of the metal nanowire mesh, the first metal wires may differ from the second metal wires in average spacing between adjacent wires in the same layer.

The methods of making metal nanowire mesh described herein allow scaling the process to larger areas with nanoscale features. The substrate below the BCP may be simply silicon or any material that stabilizes the BCP during alignment, for example, the material may not play a role in the shear alignment except to attach the BCP to a substrate. Methods described herein have fabricated metal nanowire mesh as large as 3 cm² and 4 cm² areas. Thus, scaling the process to a larger area may involve increasing force but may not involve increasing processing time. Ideally, to shear align two layers of nanowires to produce a mesh across a 4 inch wafer may require approximately 3 hours following the methods described herein. In addition, the methods of metal nanowire mesh fabrication described herein may be compatible with larger-scale patterning.

Various embodiments described below include a method to create a planar sheet of mesh with fine-tuned spaces of varying geometries that have uniform pitch between the spaces.

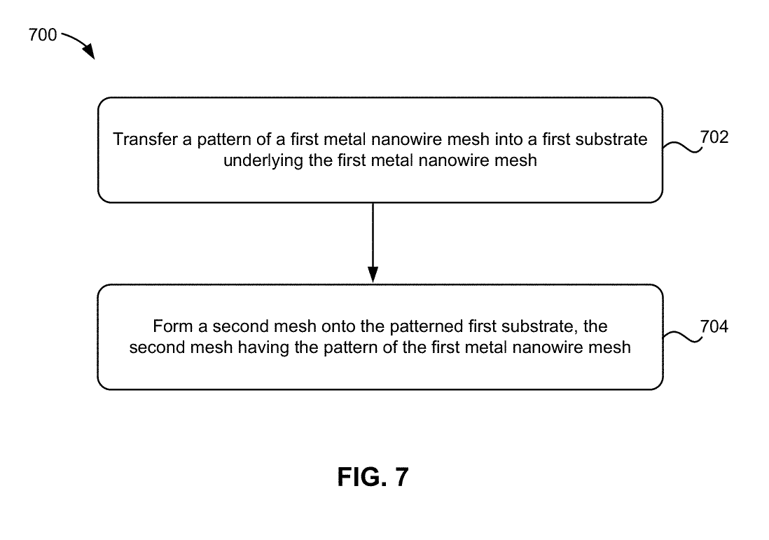

FIG. 7 shows a method 700, according to one embodiment, for creating second mesh, in accordance with one embodiment. As an option, the present method 700 may be implemented to create structures, devices such as those shown in the other FIGS. described herein. Of course, however, this method 700 and others presented herein may be used to form structures for a wide variety of devices and/or purposes which may or may not be related to the illustrative embodiments listed herein. Further, the methods presented herein may be carried out in any desired environment. Moreover, more or less operations than those shown in FIGS. 1, 2, 5, 6, 7, and 8 may be included in method 700, according to various embodiments. It should also be noted that any of the aforementioned features may be used in any of the embodiments described in accordance with the various methods.

Looking to FIG. 7, the first step 702 of method 700 includes transferring a pattern of a first metal nanowire mesh into a first substrate underlying the first metal nanowire mesh. In some embodiments, the first metal nanowire mesh may be formed following the methods described herein (method 100, FIG. 1, and method 500, FIG. 5).

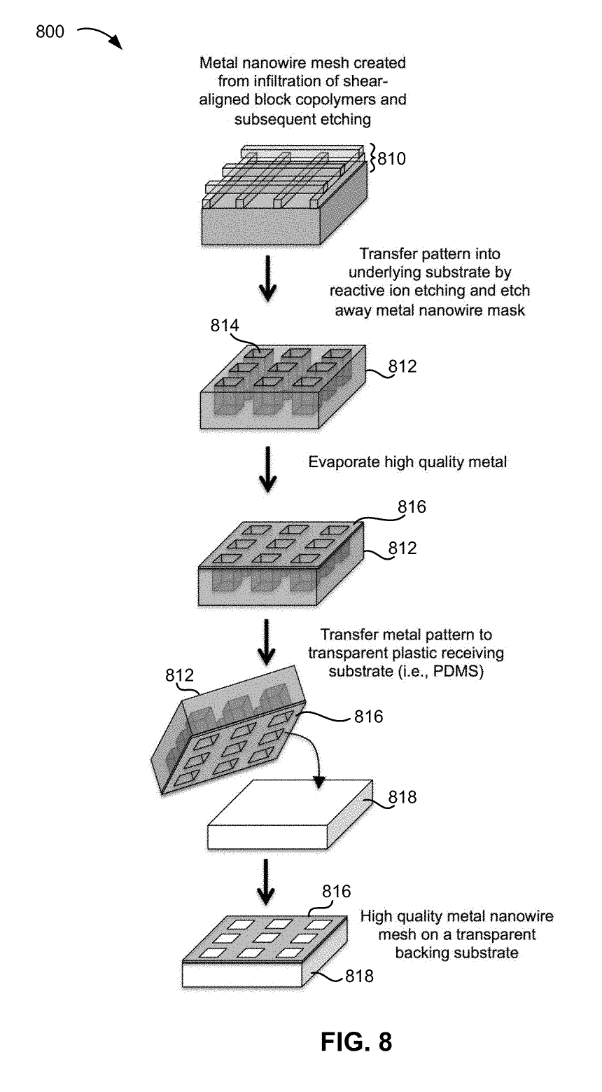

As illustrated in an exemplary embodiment in FIG. 8, the metal nanowire mesh 810 may be a fine-tuned mask to create a pattern 814 on the first substrate.

According to some embodiments, the process to transfer a pattern 814 of the first metal nanowire mesh 810 into the first substrate 812 may include, but not limited to, reactive ion etching that may also etch away the metal nanowire mesh 810.

Looking back to FIG. 7, in some embodiments of method 700, step 702 may further include removing remaining portions of the first metal nanowire mesh from the first substrate by known techniques in the art.

Step 704 of method 700 includes forming a second mesh onto the patterned first substrate, the second mesh having the pattern of first metal nanowire mesh. In some embodiments, the second mesh may include metal. In other embodiments, the second mesh may include silicon. In various embodiments, the second mesh may be planar.

As illustrated in an exemplary embodiment in FIG. 8, forming a second mesh 816 onto the patterned 814 first substrate 812 may include known techniques of evaporating material, for example, metal or silicon, by chemical vapor deposition, sputtering amorphous metal oxides etc. Alternatively, polymer or organic molecule meshes may be created, as well, by “inking” the substrate with the polymer or organic molecule. The substrate may be inked by immersing it in a polymer or organic molecule solution or by evaporating the material or spincoating a solution of the solution atop the substrate.

In some embodiments, as illustrated in method 800 of FIG. 8, the method may include transferring the second mesh 816 to a second substrate 818. In one embodiment, the second substrate 818 may be a receiving substrate, for example but not limited to, a transparent plastic receiving substrate (e.g. PDMS). In a preferred embodiment, the receiving substrate may allow better adherence of the mesh material to the receiving substrate than to the patterned substrate. In other words, a polymer material or polymer-coated receiving substrate may increase adhesion of mesh material.

In use, the metal nanowire mesh and methods of making them described herein may be important for electronics and solar cell industry. The metal nanowire mesh may be fabricated as a conductive, transparent, and flexible electrode material. For example, the metal nanowire mesh may be useful as a replacement for indium tin oxide (ITO) for use in solar cells or electronic displays.

Furthermore, the metal nanowire mesh on a substrate may be useful as a mask for creating silicon nanowires of varying geometries. These might be useful in sensing, photonic applications, catalysis, etc.

Moreover, the metal nanowire mesh and methods of making same described herein may be useful as a substrate for enhanced molecular sensing by Raman scattering.

While various embodiments have been described above, it should be understood that they have been presented by way of example only, and not limitation. Thus, the breadth and scope of an embodiment of the present invention should not be limited by any of the above-described exemplary embodiments, but should be defined only in accordance with the following claims and their equivalents.

The inventive concepts disclosed herein have been presented by way of example to illustrate the myriad features thereof in a plurality of illustrative scenarios, embodiments, and/or implementations. It should be appreciated that the concepts generally disclosed are to be considered as modular, and may be implemented in any combination, permutation, or synthesis thereof. In addition, any modification, alteration, or equivalent of the presently disclosed features, functions, and concepts that would be appreciated by a person having ordinary skill in the art upon reading the instant descriptions should also be considered within the scope of this disclosure.

1. A method for creating the metal nanowire mesh as recited in claim 17, the method comprising:
forming a first layer of block copolymer;
causing the block copolymer to become aligned in approximately straight lines;
infiltrating one phase of the block copolymer with a metal;
removing the block copolymer whereby the metal remains after the block copolymer is removed;
forming a second layer of block copolymer;
causing the block copolymer in the second layer to become ordered in approximately straight lines oriented at an angle from greater than 0 degrees to 90 degrees from a mean direction of longitudinal axes of the remaining metal;
infiltrating one phase of the block copolymer in the second layer with a second metal; and
removing the block copolymer in the second layer whereby the second metal remains above the metal after the block copolymer in the second layer is removed.

2. The method as recited in claim 1, wherein the metal and the second metal have a same composition.

3. The method as recited in claim 1, wherein the metal and the second metal have a different composition.

4. The method as recited in claim 1, wherein at least one of the infiltrating steps includes soaking the respective layer in a metal salt solution.

5. The method as recited in claim 1, comprising sintering the metal prior to forming the second layer of block copolymer.

6. The method as recited in claim 1, comprising sintering the second metal after removing the block copolymer in the second layer.

7. The method as recited in claim 1, wherein an average diameter of the metal from the first layer and/or the second metal is in a range of about 8 to about 50 nanometers.

8. The method as recited in claim 1, wherein an average diameter of the metal from the first layer is at least 10% greater or smaller than an average diameter of the second metal.

9. The method as recited in claim 1, wherein an average spacing between commonly-aligned strips of at least one of the metals is in a range of about 30 to about 100 nanometers.

10. A method for creating the metal nanowire mesh as recited in claim 17, the method comprising:
forming a first layer of block copolymer;
causing the block copolymer to become ordered in approximately straight lines;
inducing crosslinking in the block copolymer;
forming a second layer of block copolymer above the first layer;
causing the block copolymer in the second layer to become ordered in approximately straight lines oriented at an angle from greater than 0 degrees to 90 degrees from a mean direction of longitudinal axes of the lines of the first layer;
infiltrating one phase of the block copolymer in each layer with a metal; and
removing the block copolymers in the first and second layers whereby the metal remains after the block copolymer is removed.

11. The method as recited in claim 10, wherein the infiltrating step includes soaking the layers in a metal salt solution.

12. The method as recited in claim 10, comprising sintering the metal after removing the block copolymers.

13. The method as recited in claim 10, comprising masking the layers of block copolymers and removing an unmasked portion thereof for patterning the layers prior to the infiltrating.

14. The method as recited in claim 10, wherein an average diameter of the metal from the first layer and/or the metal from the second layer is in a range of about 8 to about 50 nanometers.

15. The method as recited in claim 10, wherein an average diameter of the metal from the first layer is at least 10% greater or smaller than an average diameter of the second metal.

16. The method as recited in claim 10, wherein an average spacing between commonly-aligned strips of at least one of the metals is in a range of about 30 to about 100 nanometers.

17. A metal nanowire mesh, comprising:
first metal wires oriented in approximately straight lines; and
second metal wires on the first metal wires, the second metal wires being oriented in approximately straight lines oriented at an angle from greater than 0 degrees to 90 degrees from a mean direction of the lines of the first metal wires,
wherein an average diameter of at least one of the first and second metal wires is in a range of about 8 to about 50 nanometers.

18. The metal nanowire mesh as recited in claim 17, wherein an average spacing between the first metal wires is in a range of about 30 to about 100 nanometers.

19. The metal nanowire mesh as recited in claim 17, wherein an average spacing between the first metal wires varies by less than 20% along lengths thereof.

20. The metal nanowire mesh as recited in claim 17, wherein the first metal wires have at least one difference from the second metal wires, the difference being selected from a group consisting of: composition, average diameter, and average spacing between adjacent wires.

21. A method for creating a second mesh, the method comprising:
transferring a pattern of a first metal nanowire mesh into a first substrate underlying the first metal nanowire mesh; and
forming a second mesh onto the patterned first substrate, the second mesh having the pattern of the first metal nanowire mesh.

22. A method as recited in claim 21, further comprising, removing the first metal nanowire mesh from the first substrate.

23. A method as recited in claim 21, wherein the second mesh is comprised of metal.

24. A method as recited in claim 21, wherein the second mesh is comprised of silicon.

25. A method as recited in claim 21, further comprising, transferring the second mesh to a second substrate.

26. A method as recited in claim 21, wherein the second mesh is planar.
